(19) United States
(12) Patent Application Publication
(10) Pub. No.: US 2002/0086512 A1
(43) Pub. Date: Jul. 4, 2002

(54) Method of forming solder bumps

(76) Inventor: Yih Muh Min, Chiung-Lin Shiang (TW)

Correspondence Address: J.C. Patents, Inc., 4 Venture, Suite 250, Irvine, CA, 92618, US

(21) Appl. No.: 09/761,926

(22) Filed: Jan. 17, 2001

(30) Foreign Application Priority Data
Dec. 29, 2000 (TW) 89128260

(51) Int. Cl. H01L 21/44

(52) U.S. Cl. 438/613

(57) ABSTRACT

A method of forming solder bumps provides a wafer, which comprises a plurality of I/O pads, a passivation layer, an isolating metal layer and a UBM layer. A photoresis layer is formed on a location of forming solder sump on the UBM layer. A portion of the UBM layer that is situated outside the location of forming solder bump is removed. The underlying isolating metal layer is exposed.

A thick photoresist layer is applied on the UBM layer and the isolating layer, wherein by exposing and photolithography methods to remove the thick photoresis layer, which is formed on the locations of forming solder bumps. A printing method is used to fill a solder paste into an opening of the photoresist later. A reflow process is carried out to reflow the solder paste. After the reflow process, the photoresist layer is removed, and finally the isolating metal layer is also removed. A wafer with solder bumps is thus formed.

### CROSS-REFERENCE TO RELATED APPLICATION

This application claims the priority benefit of Taiwan application serial no. 89128260, filed Dec. 29, 2000.

### BACKGROUND OF THE INVENTION

1. Field of Invention

The present invention relates generally to a method of forming solder bumps. More particularly, the present invention relates to a method of improving a fabrication of solder bumps on a wafer.

2. Description of the Related Art

With the increasing need for high-density devices for use in lightweight, portable electronics, there has been a gradual shift in integrated circuits sizes and their package configurations. This gradual shift has resulted in developing various techniques in different package types.

There are generally three types of methods of connecting a chip to a carrier: a wire bonding method, a tape automated bonding (TAB) method and a flip chip (F/C) method. However, the TAB and the (F/C) package methods require to form solder bumps on the wafer for electrically connecting the chip to the carrier. Solder bumps with uniform-height are very important for a good bonding between the chip and the carrier. The fabricating technique of solder bumps develops towards forming solder bumps, which have good conductivity with even and uniform height, and fine pith.

FIGS. 1A-1C illustrate cross-sectional views of a method of forming solder bumps in accordance with a conventional method. Referring to FIG. 1A, a wafer 100 is provided, and a plurality of I/O pads 102. A passivation layer 104 is formed over the wafer, and exposes central regions of the I/O pads 102. A under bump metal (UBM) layer 106 is formed over the passivation layer 104 and the I/O pads 102. The UBM layer 106 comprises a plurality of layers, which are a titanium layer 106a and a copper layer 106b. The titanium layer 106a serves as a barrier layer to prevent ions from the solder paste penetrating into the underlying layers and devices. The copper layer 106b provides a good adhesion for the solder paste.

Referring to FIG. 1B, a patterned photoresist layer 108, which is formed on the UBM layer 106 comprises a plurality of openings, wherein the openings are defined for locations of forming solder bumps. An electroplating method is carried out to form a solder layer 110 on a part of UBM layer 106 that is not covered by the photoresist layer 108. The thickness of the solder layer 110 is controlled by electroplating parameters such as an electroplating solution, or the current distribution.

FIG. 1C illustrates the photoresist layer 108 is removed and a reflow process is carried out. The solder layer 110 is reflowed to form a solder bump 112, which then serves as a mask by removing a portion of UBM layer 106 that is not covered and protected by the solder bump 112. Thus a wafer with solder bumps is formed.

From the above-mentioned conventional method, the solder bump is formed on the UBM layer by electroplating method. During the formation process, there is a problem of current distributed unevenly throughout the wafer, solder bumps with uniform-height will form to cause a bonding problem between the chip and the carrier later. The electroplating method uses a process of depositing the metal ions from the plating solution to form a solder layer, wherein the deposition process has a very low rate of forming solder layer. Thus the productivity is reduced.

Another problem of the electroplating process of the conventional method is a ratio control problem between tin and lead of the solder layer. The ratio of tin and lead ions in the solder layer is preferably 63:37. However the formation ratio of tin and lead in the solder layer during the deposition process of metal ions from the plating solution is very difficult to control, thus inconsistent ratio of tin/lead in the solder layer can lead to the eutectic temperature of the solder layer difficult to be determined, which causes the reflow temperature difficult to be controlled.

### SUMMARY OF THE INVENTION

The present invention provides a method of forming solder bumps by using a printing method. The printing method uses a solder paste, which contains a constant ratio of tin and lead ions, thus the ratio can be actuarially controlled. The problems caused by the electroplating method can be omitted.

To achieve the foregoing and other objects and in accordance with the purpose of the present invention, the present invention provides a method of forming solder bumps comprising: a wafer, which is provided comprises a plurality of I/O pads, a patterned passivation layer, a UBM layer and an isolating layer. A photoresis layer is formed on a location of forming solder bump on UBM layer. A portion of the UBM layer that is situated outside the location of forming solder bump is removed. The underlying isolating metal layer is exposed. A thick layer of photoresist is applied on the UBM layer and the isolating layer, wherein by exposing and photolithography methods to remove the thick photoresist layer, which is formed on the locations of forming solder bumps. A printing method is used to fill a solder paste into an opening of the photoresist later. A reflow process is carried out to reflow the solder paste. After the reflow process, the photoresist layer is removed, and finally the isolating metal layer is also removed. A wafer with solder bumps is thus formed. Because the photoresist layer is formed on the isolating layer, it can be removed completely and easily.

Both the foregoing general description and the following detailed description are exemplary and explanatory only and are not restrictive of the invention, as claimed.

### BRIEF DESCRIPTION OF THE DRAWINGS

FIGS. 1A-1C illustrate cross-sectional views of a method of forming solder bumps in accordance with a conventional method; and

FIGS. 2A-2D illustrate cross-sectional views of a method of forming solder bumps in accordance with a preferred embodiment of the present invention.

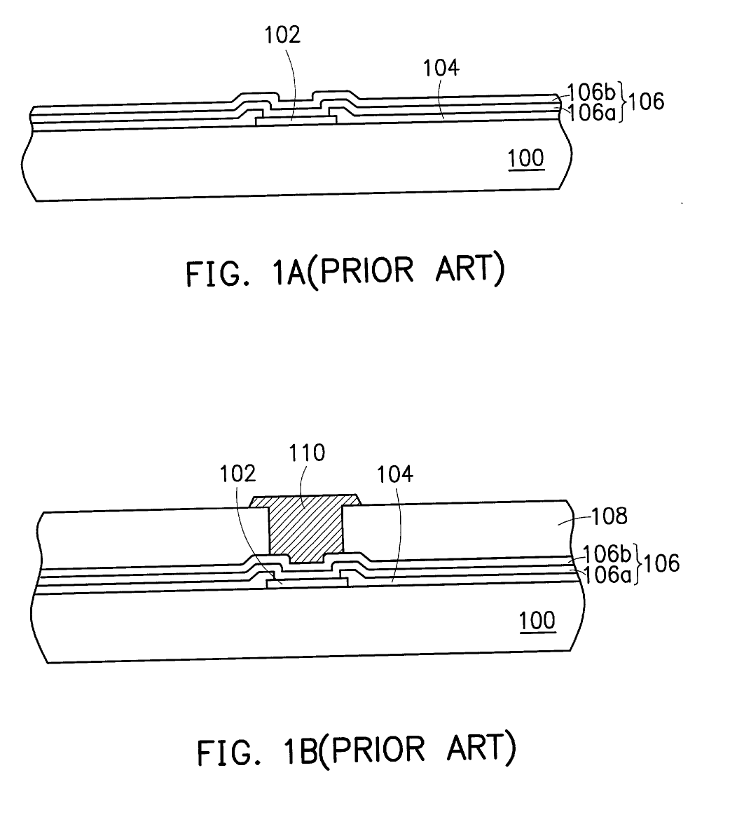

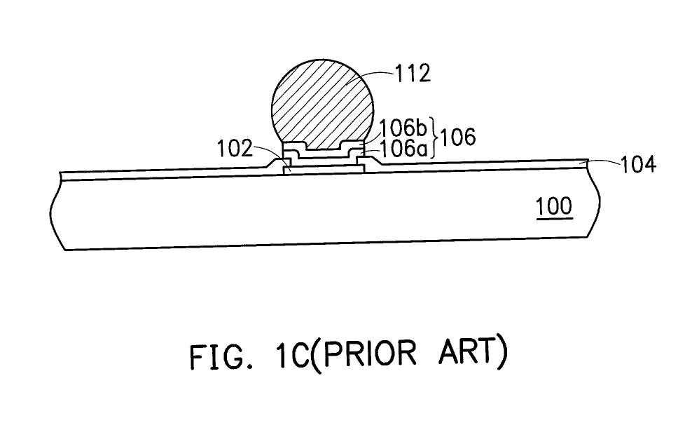

### DESCRIPTION OF THE PREFERRED EMBODIMENTS

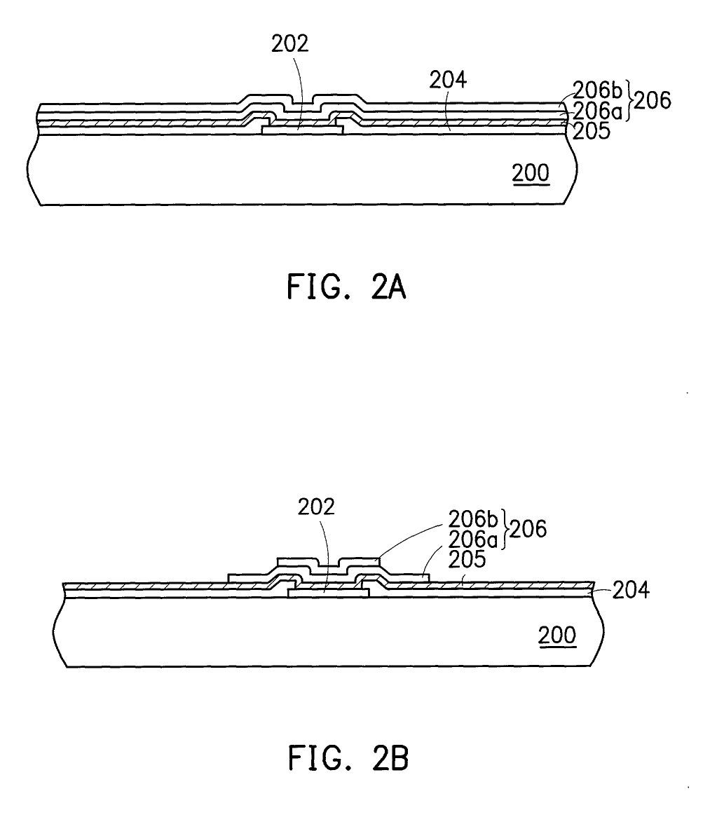

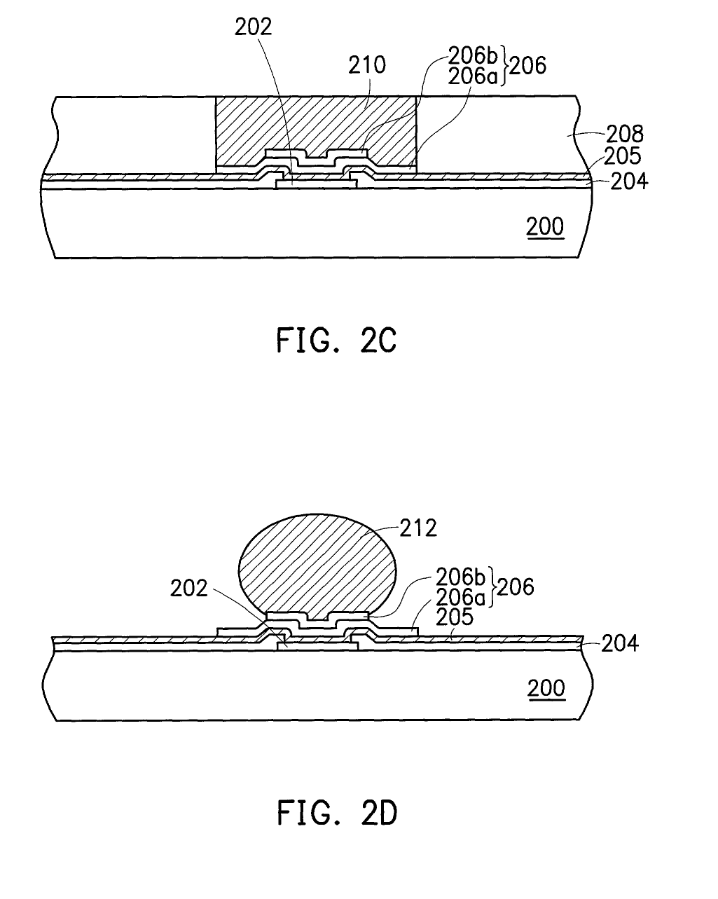

FIGS. 2A-2D illustrate cross-sectional views of a method of forming solder bumps in accordance with a preferred embodiment of the present invention. Referring to FIG. 2A, providing a wafer 200, in which a plurality of I/O pads 202 and a passivation layer 204 are formed on the wafer 200. The passivation layer 204 covers the periphery of the I/O pads 202, and the I/O pads are made of material such as aluminum. The passivation layer 204 is preferably made of material such as silicon oxide, silicon nitride (Si₃N₄) or polyimide etc. An isolating layer 205, which is formed on the wafer 200 must consist of an isolating function between a photoresist and the passivation layer 204. Follow, an under bump metal (UBM) layer 206 is formed, which is a structure comprising a plurality of layers, for example, at least comprising a first metal layer 206a and a second metal layer 206b. Amongst, a thickness of the first metal layer 206a is approximately 3000 Å, and a thickness of the second metal layer 206b is approximately 7000 Å. The above-mentioned UBM layer 206, which comprises two layers has a good protection function. The UBM layer 206 can serve as a barrier to prevent ions of the solder bumps penetrate into the underlying layers and devices, thereby protecting the underlying layers and devices from damaging.

Referring to FIG. 2B, a portion of UBM layer 206, which is situated outside of a location for growing solder bumps is removed. Only a portion of UBM layer 206, which is on the I/O pads 202 of the location for growing solder bumps is kept. A portion of the isolating metal layer 205 at the region outside the locating for growing solder bumps is exposed. A method of removing the UBM layer 206 is to use a photoresist layer (not shown) covering the UBM layer 206 on the I/O pads, and use a etching method to remove a portion of the UBM layer 206 that is not covered by the photoresist layer.

Referring to FIG. 2C, a photoresist layer 108 is formed for covering the exposed isolating metal layer 205. The photoresist layer 208 is corresponding to a plurality of openings 209 of the I/O pads 202, and a thickness of the photoresist layer 208 is approximately above 70 μm. A printing method is used to fill the solder paste 210 into the openings 209 of the photoresist layer 208. A reflow process is carried out to melt the solder paste 210 in order to form solder bumps. After the formation of solder bumps, the photoresist layer 208 is removed, and because the thickness of the photoresist layer 208 can be increased above 70 μm, therefore uniform-height of solder bumps can be formed. A problem of forming uneven-height of solder bumps can be prevented, the yield loss of the production can be extremely reduced.

FIG. 2C, after the reflow process, if there is no the isolating metal layer 205 to isolate the photoresist layer 208 from the passivation layer 204, the photoresist layer 208 will not be able to be removed completely afterward. When the photoresist is formed on the passivation layer 204, the isolating metal layer 205 can allow the photoresist layer 208, which is made of organic material, to be removed completely. Therefore, the present invention provides a method of removing all the residues formed by the solder particles on the wafer. The present invention can also apply for removing techniques on the photoresist layer after a high temperature process, therefore the present invention is not limited to the fabrication of solder bumps.

Referring to FIG. 2D, after removing the photoresist layer 208 (not shown), the exposed isolating metal layer 205 is removed until the passivation layer 204 on the wafer is exposed. Because the photoresist layer 208 is formed on the exposed isolating layer 205, therefore after the reflow process, the photoresist layer 208 can be removed completely when the isolating metal layer 205 is removed. Thus a contamination problem will not occur afterward during the packaging process.

From the above-mentioned embodiment, the present invention, which provides a method of forming solder bumps comprises several advantages:

1. The present invention uses a printing method instead of an electroplating method of forming solder bumps, the production process is much simple and faster.

2. The method of the present invention provides an improving method of forming uniform-height solder bumps. The printing method of the present invention can maintain the consistent ratio between tin ions and lead ions, and the coplanarity of the solder bumps structure can be thus improved.

3. The present invention dose not need to deal with a waste-stream problem of an electroplating solution, the printing process is much simple than the electroplating process, thus the cost can be reduced to increase the productivity.

4. The charateristic of the present invention is to remove a portion of the UBM layer first, then exposing the underlying isolating metal layer, thus forming a photoresist layer on the isolating layer. Due to the charateristic of this method, the photoresist layer can be removed easily after the reflow process.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of forming solder bumps, suitable for fabricating solder bumps on a wafer, wherein the wafer comprises a plurality of I/O pads and a passivation layer, the steps of the method comprise:
forming an isolating metal layer on the I/O pads and the passivation layer;
forming an under bump metal layer (UBM) on the isolating metal layer;
defining a location of forming a bump, wherein a portion of the UBM layer that situated outside the location of forming the bump is removed to expose the isolating metal layer;
forming a photoresis layer, having a plurality of openings, wherein each opening of the photoresis layer is corresponded to the location of the bump;
using a printing method to fill a solder paste into the openings;
reflowing the solder paste;
removing the photoresist layer; and
exposing the isolating metal layer.

2. The method of claim 1, wherein the isolating metal layer comprises a function of isolating the photoresist layer from the passivation layer.

3. The method of claim 1, wherein the solder paste is made of materials comprising tinlead alloy paste (Sn₆₃Pb₃₇) or other alloys that can form bumps.
